(19) United States
(12) Patent Application Publication
(10) Pub. No.: US 2022/0117080 A1
(43) Pub. Date: Apr. 14, 2022

(54) BALL GRID ARRAY CHIP (BGA) PACKAGE COOLING ASSEMBLY WITH BOLSTER PLATE

(71) Applicant: Intel Corporation, Santa Clara, CA (US)

(72) Inventors: Phil GENG, Washougal, WA (US); Sandeep AHUJA, Portland, OR (US); Ralph V. MIELE, Hillsboro, OR (US); David SHIA, Portland, OR (US); Jeffory L. SMALLEY, Olympia, WA (US); Casey WINKEL, Hillsboro, OR (US)

(21) Appl. No.: 17/555,340

(22) Filed: Dec. 17, 2021

(51) Int. Cl. H05K 1/02; H01L 23/40; H05K 1/18

(52) U.S. Cl. CPC H05K 1/0271; H01L 23/40; H05K 7/1489; H05K 2201/2009; H05K 2201/10734; H05K 1/181

(57) ABSTRACT

An apparatus is described. The apparatus includes a ball grid array (BGA) chip package cooling assembly includes a back plate and a bolster plate. The bolster plate has frame arms. The BGA chip package is to be placed in a window formed by the frame arms and soldered to a region of a printed circuit board. The frame arms surround the region. The printed circuit board is to be subjected to a compressive force between the back plate and the bolster plate.

### BACKGROUND

System design engineers face challenges, especially with respect to high performance data center computing, as both computers and networks continue to pack increase their levels of performance resulting in higher heat dissipation. Creative packaging solutions are therefore being designed to keep pace with the thermal requirements of such aggressively designed systems.

### FIGURES

A better understanding of the present invention can be obtained from the following detailed description in conjunction with the following drawings, in which:

FIGS. 1a, 1b, 1c, 1d, 1e, 1f, and 1g pertain to a land grid array (LGA) chip package cooling assembly (prior art);

FIGS. 2a and 2b pertain to a response of the cooling assembly of FIGS. 1a-f to board warpage (prior art);

FIGS. 3a, 3b and 3c pertain to a ball grid array (BGA) chip package cooling assembly (prior art);

FIGS. 4a and 4b pertain to a response of the cooling assembly of FIG. 3a-c to board warpage;

FIGS. 5a, 5b, 5c, 5d and 5e pertain to an improved BGA chip package cooling assembly;

FIG. 6 pertains to another improved BGA chip package cooling assembly;

FIG. 7 shows a system;

FIG. 8 shows a data center;

FIG. 9 shows a rack.

### DETAILED DESCRIPTION

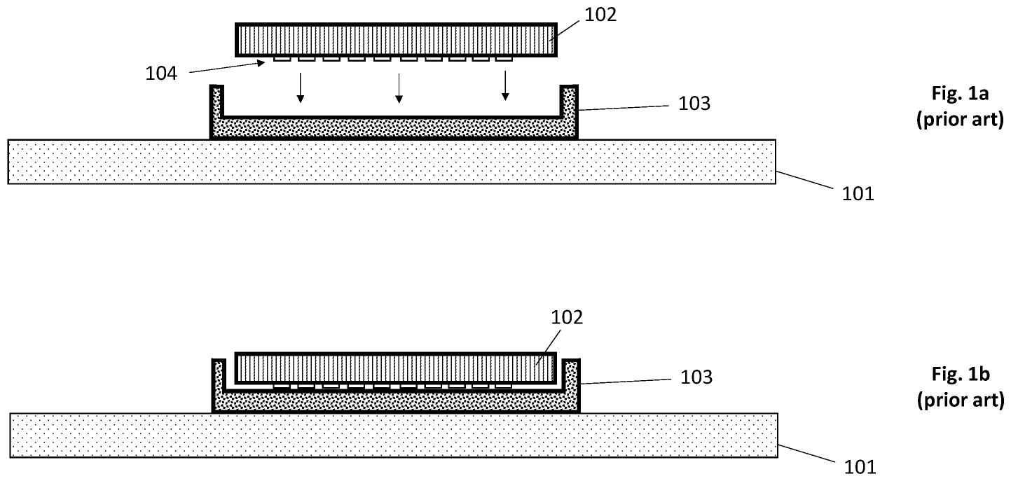

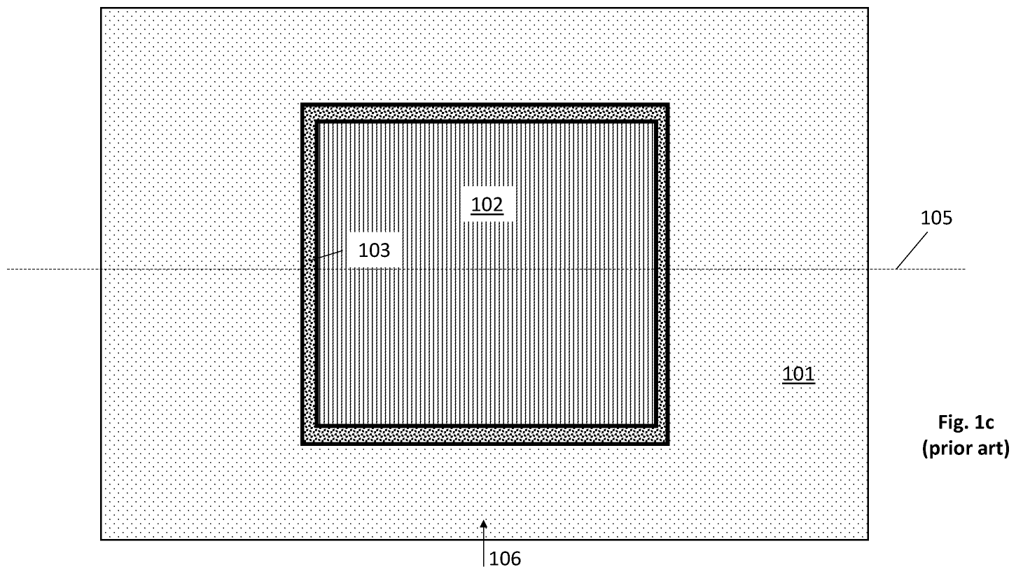

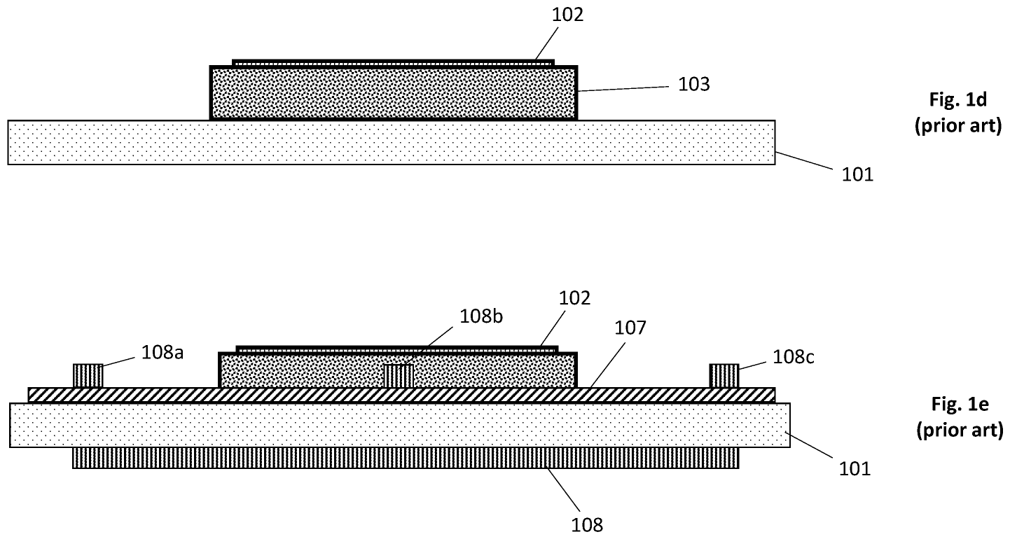

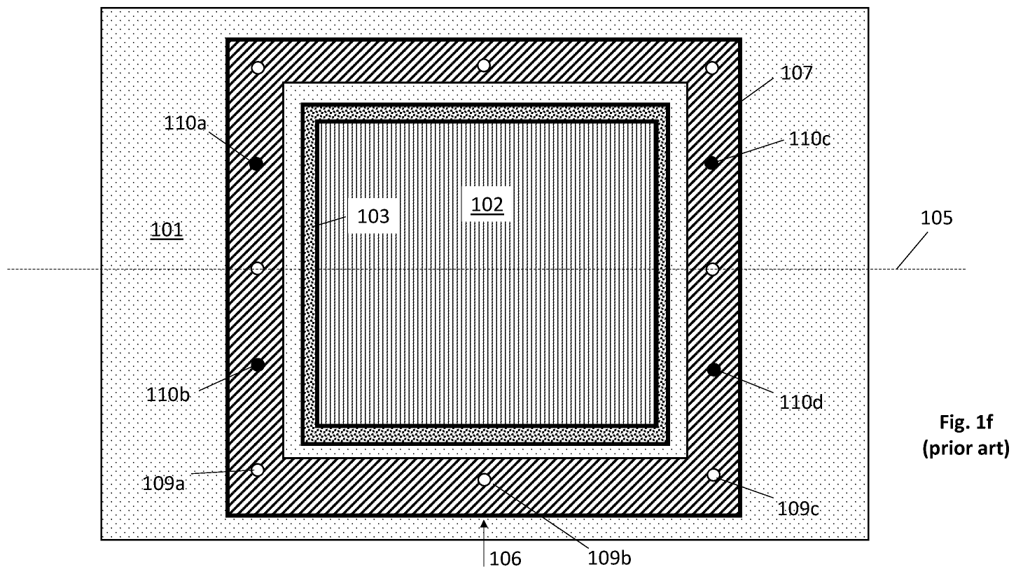

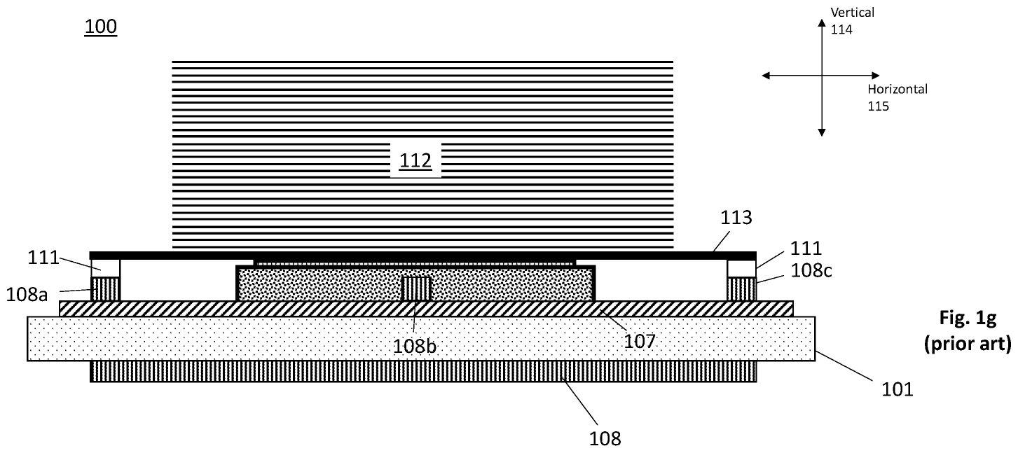

FIGS. 1a through 1g pertain to a cooling assembly for a land grid array (LGA) semiconductor chip package 102. As observed in FIGS. 1a and 1b, a semiconductor chip package 102 having one or more semiconductor chips and an LGA interface 104 is plugged into a socket 103 that is affixed to an electronic circuit board 101 (also referred to as a printed circuit (PC) board 101). Upon being plugged into the socket 103, the chip package 102 is mechanically and electrically coupled to the socket 103. The socket 103 includes electrical structures that couple the LGA I/Os 104 to corresponding I/Os on the circuit board 101 (not shown in FIGS. 1a and 1b for illustrative ease).

FIG. 1b shows a cross sectional view along axis 105 of FIG. 1c (which shows a top down view). FIG. 1d shows the same chip package 102 and socket 103 when viewed along ray 106 of FIG. 1c. Here, only the top surface of the chip package 102 is observed because the remainder of the chip package 102 is submerged into the well of the socket 103.

As observed in FIG. 1e, a bolster plate 107 is placed on the chip package side of the electronic circuit board 101 and a back plate 108 is placed on the opposite side of the electronic circuit board 101. A top down view of the bolster plate 107 is observed in FIG. 1f. As can be seen in FIG. 1f, the bolster plate 107 is a frame-like structure. The bolster plate 107 is positioned on the printed circuit board 101 such that the socket 103 is within the open space of the bolster plate 107.

Also, referring to FIGS. 1e and 1f, the back plate 108 has studs that are aligned with holes in the bolster plate 107. For example, studs 108a, 108b and 108c of FIG. 1e are aligned with holes 109a, 109b, 109c of FIG. 1f. For ease of drawing, only holes 109a, 109b, 109c of FIG. 1f are labeled because only studs 108a, 108b, 108c are observable from the side view of FIG. 1e. However, as suggested by FIG. 1f, similar studs and aligned holes exist around the periphery of the socket 103.

Referring to FIG. 1e, fixturing elements (e.g., screws, bolts, etc.) are then applied to the studs 108a,b,c and tightened to rigidly secure the bolster plate 107 to the back plate 108 (for ease of drawing the fixturing elements are not depicted).

Then, as observed in FIG. 1g, a heat sink 112 having a base 113 is mounted to the bolster plate 107. Referring back to FIG. 1f, the bolster plate 107 also includes additional mechanical interfacing elements 110 (e.g., studs, mounts, holes, etc.) that are used to mount the heat sink base 113 to the bolster plate 107. The bottom of the heat sink base 113 has corresponding mechanical features to interface with the interface elements 110 (e.g., holes, receptors, studs, etc.).

Commonly, some kind of spring-loaded attachment hardware 111 is coupled between the bolster plate 107 (e.g., as part of the interfacing elements 110) and the heat sink base 113 to press the heat sink base 113 against the lid of the chip package 103 (notably, attachment hardware 111 is behind studs 108a and 108c in the side view of FIG. 1g). The spring-loaded attachment hardware 111 typically includes some kind of spring element (e.g., coil spring, metal tab, etc.) that is compressed or stretched when the cooling assembly 100 is in its nominal state.

The stretching/compressing of the spring element causes the spring element to exert a “loading force” that tries to pull the heat sink base 113 and bolster plate 107 closer together. Here, the socket's LGA leads in the socket well exert considerable push-back against the I/Os 104 on the underside of the chip package 103 (because of the spring-like nature of the socket leads). The aforementioned spring-loading between the heat sink base 113 and bolster plate 107 is designed to overcome this push back (the heat sink base 113 presses against the lid of the chip package 102 thereby preventing the chip package 102 from popping out of the socket 103).

With larger and larger I/Os per chip, the push back exerted by the socket 103 is becoming increasingly large which, in turn, drives extreme loading forces (greater than 700 lbs) to counteract the push back. Such extreme loading forces necessitate the use of the bolster plate 107. That is, if the bolster plate 107 did not exist (such that the heat sink 112 and corresponding spring-loading hardware 111 was mounted to the back plate 108), the printed circuit board 101 would warp in response to the loading force. The bolster plate 107 keeps the high loading force above the board 101 rather than allow the loading force to run through the board 101. The former does not cause warpage, the later would.

The circuit board 101 can warp, however, in response to thermal stresses. Here, when the board 101 is operational, the semiconductor chips that are coupled to the board 101 will dissipate heat that is transferred to the board 101. Because the board 101 is a multi-layer structure composed of different materials with different thermal coefficients of expansion, the board 101 will suffer internal stresses in response to the heat which causes the board 101 to warp.

The warping of a printed circuit board 101 can stress the electrical connections between the underside of the socket 103 and the printed circuit board 101 and/or the electrical connections in the well of the socket 103 and the underside of the chip package 102. Thankfully, the socket leads on both the underside of an LGA socket 103 (which mate with the circuit board 101) and within the well of the socket 103 (which mate with the chip package I/Os 104) are spring-like and are able to absorb stresses induced into the I/O structure by the thermally induced board warpage.

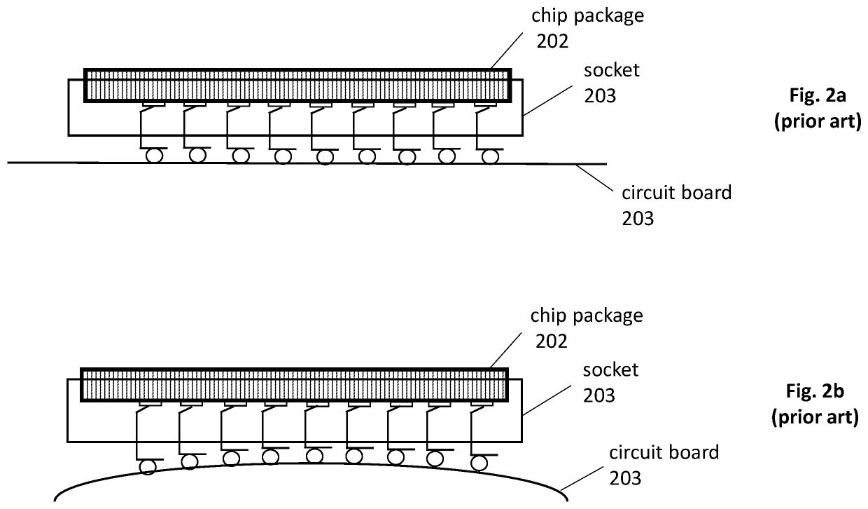

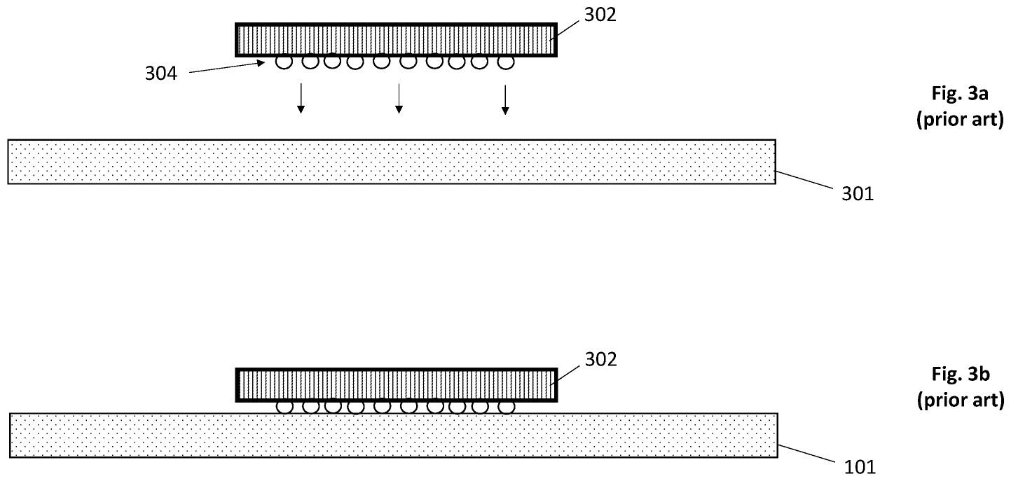

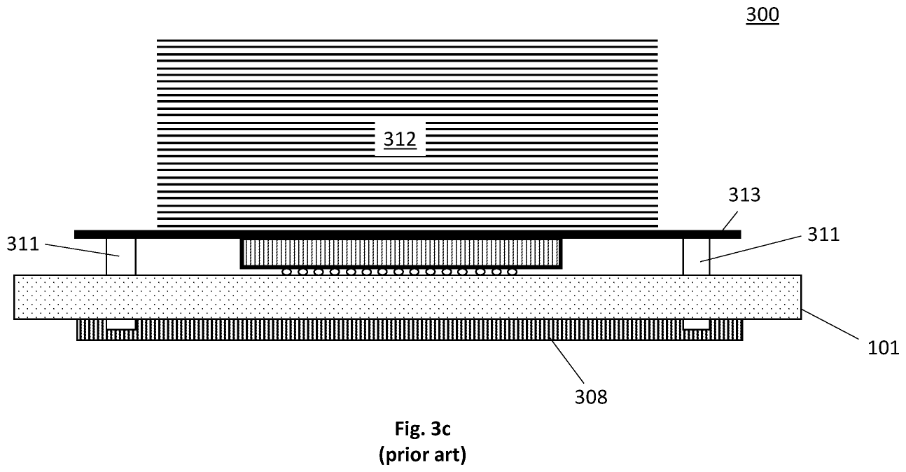

FIGS. 2a and 2b depict the situation in more detail. FIG. 2a shows a cross section of the socket 203 without board warpage. Notably, the socket leads on both the underside of the socket 203 and within the socket well are finger like which gives them spring-like mechanical characteristics. FIG. 2b shows the how the same structure responds to board warpage. As can be seen in FIG. 2b, the spring-like socket leads are able to stretch in response to the board warpage thereby preserving the integrity of the overall I/O structure.

Whereas FIGS. 1a-1g and 2a,b pertained to a prior art LGA chip package 102 cooling assembly 100, by contrast, FIGS. 3a, 3b, and 3b pertain to a prior art cooling assembly for a ball grid array (BGA) semiconductor chip package 302.

As observed in FIG. 3a, a BGA chip package 302 has solder balls 304 on the underside of the package 302 (as opposed to pads 104 in the case of an LGA package 102). As observed in FIG. 3b, a BGA chip package 302 is not traditionally inserted into a socket, but rather, is soldered directly to the printed circuit board 301.

FIG. 3c shows the completed assembly 300. Notably, apart from the BGA chip package 302 being soldered directly to the printed circuit board 301, the cooling assembly does not include a bolster plate. Rather, the heat sink 312 and spring loading hardware 311 is attached to the back plate 308. Because there is no socket exerting push back with the BGA package 302, the loading forces created by the spring loading hardware 311 are primarily designed to minimize movement of the heat sink 312 and are significantly less than the loading forces applied by the LGA assembly's spring loading hardware 111.

Specifically, whereas the loading forces created by the LGA assembly's spring loaded hardware 111 can be 700 lbs or higher, by contrast, the loading forces created by the BGA assembly's spring loaded hardware 311 are typically 200 lbs or less. Because the loading forces are significantly less in the BGA package 302 assembly 300, the BGA package 302 assembly 300 does not need a bolster plate.

Unfortunately, however, the ball attachment structure between the BGA package 302 and printed circuit board 301 does not posses the kind of elasticity that the leads of the LGA socket 102 possess. As such, if the printed circuit board 301 warps in response to thermally induced stress, the integrity of the solder ball connections can become compromised.

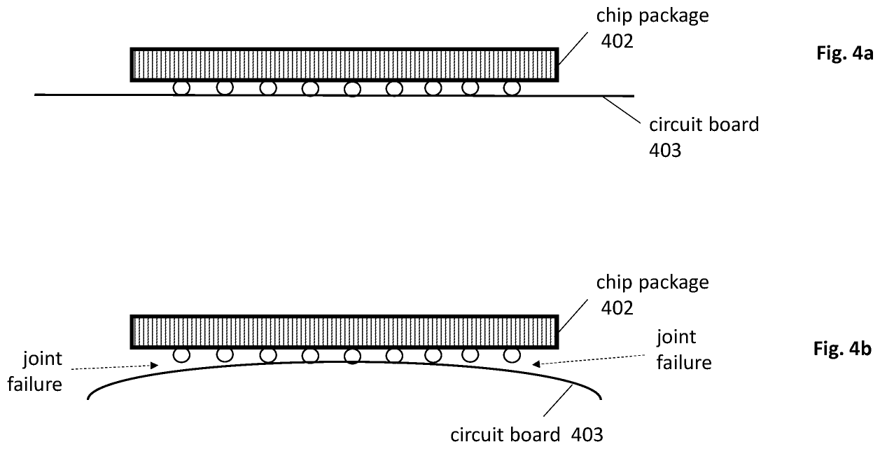

FIGS. 4a and 4b depict the situation in more detail. FIG. 4a shows nominal BGA package 302 attachment to the printed circuit board 301 without any board warpage. FIG. 4b shows the same structure after the board 302 warps. As can be seen in FIG. 4b, the solder balls toward the periphery of the chip package 302 are broken because of the amplified warping that exists toward the periphery of the package 302.

Here, heat absorbed by the printed circuit 301 board is primarily being dissipated by the one or more chips within the package 302. As the performance of the chip(s) and the number of I/Os increase with each next improvement in semiconductor chip manufacturing technology, more heat is absorbed by the board 301 over a larger surface area (the size of the package 302 increases with increasing I/Os), which, in turn, causes increasing board bending at the periphery of the chip package 302. The increased board bending at the package periphery induces significant stress to the solder balls along the periphery. The stresses can be particularly severe at the “corners” of the chip package because severe bending can exist in multiple directions.

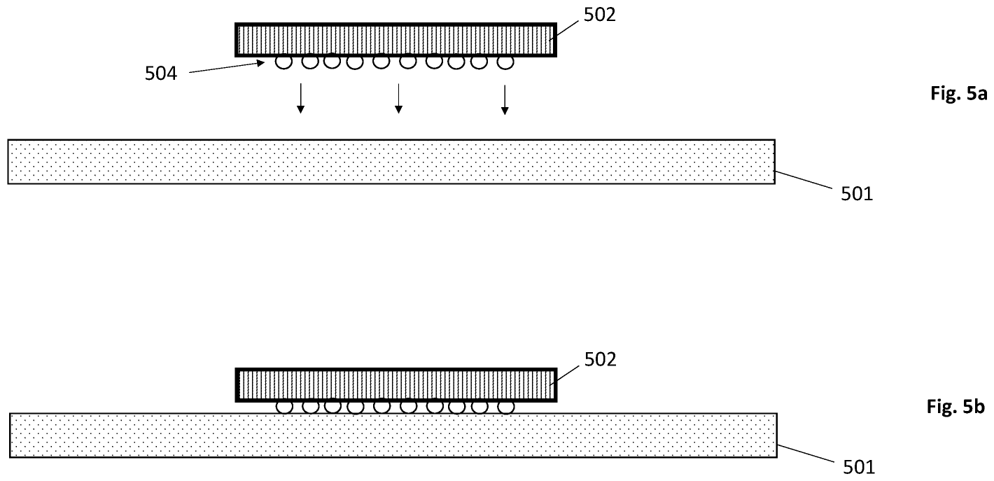

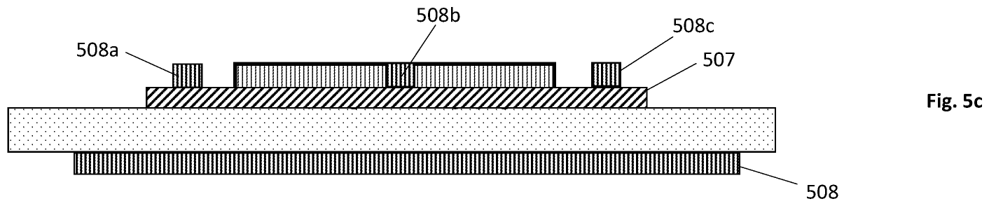

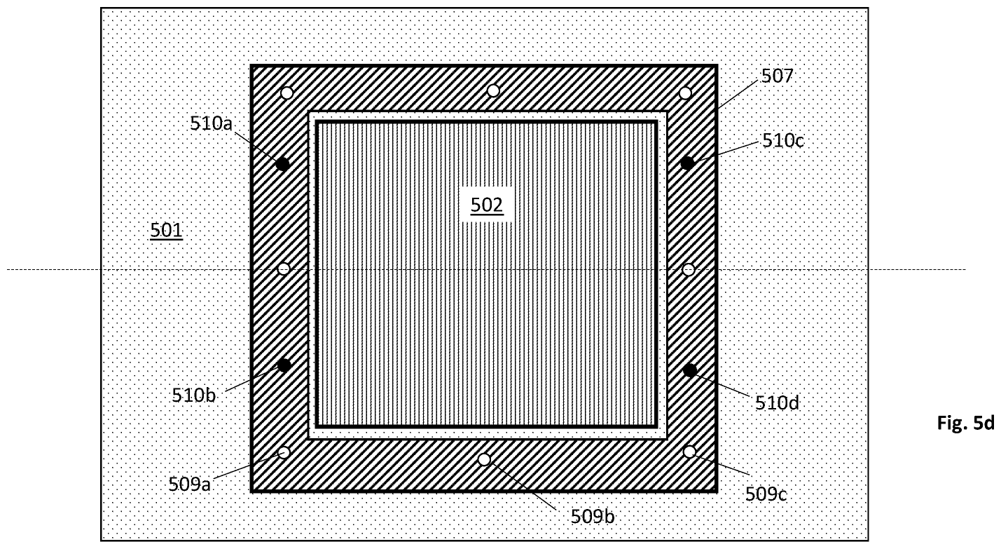

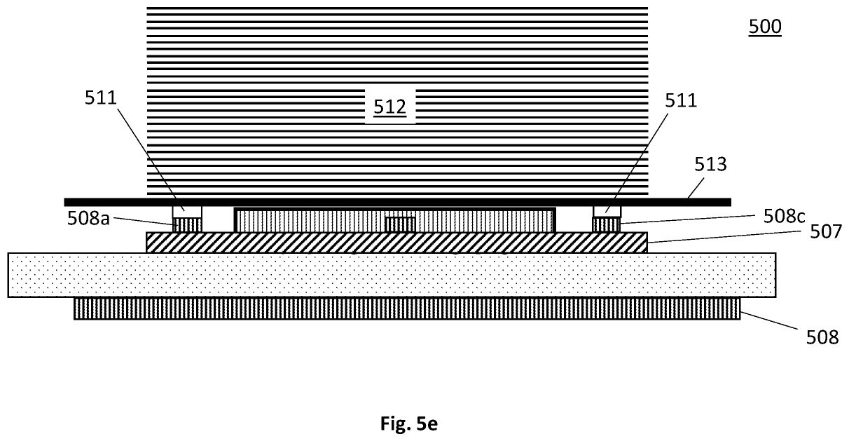

A solution, depicted in FIGS. 5a-e, is to introduce a bolster plate 507 to the cooling assembly 500 of the BGA package 502. FIGS. 5a and 5b depict the chip package 502 being soldered directly to the circuit board 501. FIG. 5c shows the structure after a back plate 508 has been mounted to the back side of the circuit board 501 and the bolster plate 507 has been placed on the chip package side of the circuit board 501.

FIG. 5d shows a top down view of the structure of FIG. 5c, as observed in FIG. 5d, the window opening in the bolster plate 507 is only slightly larger than the size of the chip package 502 so that the bolster plate's frame arms interface with the printed circuit board 501 just outside of the periphery of the chip package 502. Moreover, a number of through holes 509 are spaced around the frame (e.g., at least three holes per frame arm) through which studs in the back plate 508 are aligned (for ease of drawing, FIG. 5d only labels holes 509a,b,c because they are aligned with the only back plate studs 508a,b,c that are observable in FIG. 5c). Screws, bolts or other fixturing elements are then mated with the back plate studs to rigidly secure the bolster plate 507 with the back plate 508.

Plentiful points of contact 509 placed around the circumference of the bolster plate that are in close proximity to the periphery of the chip package 502 and that rigidly secure the bolster plate 507 to the backplate 508, with the printed circuit board 501 in between, results in an overall structure that can sufficiently diminish thermally induced warpage of the printed circuit board 101 (even for BGA packages with high heat dissipation and large footprint). Here, with the printed circuit board 501 being tightly compressed between the bolster plate 507 and the back plate 507 in the immediate footprint area of the chip package 502, the circuit board 501 will exhibit little if any warpage beneath the chip package 502 thereby preserving the integrity of the solder ball joints between the chip package 502 and the circuit board 501.

In various embodiments, the bolster plate 507 is designed substantially as observed in FIG. 5d, meaning, the shape and proportions of the bolster plate 507 are that of a simple window frame having frame arms that are thinner than, e.g., a 33% “slice” or stripe of the window opening and without any extended structures or flanges that emanate away from or extend from the frame arms. So doing keeps the mechanical emphasis on diminishing the warping of the printed circuit board beneath the BGA package 502 without further complications.

FIG. 5e shows the completed assembly with the spring loading hardware 511 being coupled between the heat sink base 513 and the bolster plate 507. Referring back to FIG. 5d, the spring loading hardware 511 is coupled to mechanical interfacing elements 510 (e.g., studs, mounts, holes, etc.) of the bolster plate 507. Because the mechanical interfacing elements 510a,b are aligned with hole 509a and because mechanical interfacing elements 510c,d are aligned with hole 509c, the spring loaded hardware 511 is only partially visible “behind” back plate studs 508a and 508c in the side view of FIG. 5e.

Notably, unlike the bolster plate 107 in the prior art LGA package cooling assembly 100 described above, the bolster plate 507 in the improved BGA package 503 assembly 500 of FIG. 5e is designed to diminish thermally induced warpage of the printed circuit board 501 (by contrast, as described above, the bolster plate 107 in the LGA package 102 assembly 100 is designed to support loading forces sufficient to overcome the push back from the LGA socket 102).

For same sized chip packages, push back forces from an LGA socket 102 are much stronger than the thermally induced forces that warp a printed circuit board. As such, the loading forces applied by the spring-like elements in the spring loading hardware 511 of the improved BGA package 502 cooling assembly 500 need not be as strong as those applied by the prior art LGA package 102 cooling assembly 100. For instance, whereas the loading forces supported by the bolster plate 107 of the LGA assembly 100 can be 700 lbs or more, by contrast, the loading forces supported by the bolster plate 507 in the improved BGA assembly 500 of FIG. 5e can be 200 lbs or less (e.g., enough to sufficiently diminish movement of the heat sink).

Said another way, the bolster plate 107 of the prior art LGA package cooling assembly 100 is designed to protect the circuit board 101 from the loading forces applied by the loading force hardware 111 between the bolster plate 107 and the heat sink 112. By contrast, the bolster plate 507 of the improved BGA package cooling assembly 500 is designed to protect the circuit board 501 from its own thermally induced stresses. The former (LGA package cooling assembly loading forces) are significantly greater than the later (thermally induced stress of the circuit board).

As a consequence, the material that the bolster plate 507 of the improved BGA package cooling assembly 500 of FIG. 5e is composed of can be weaker material (e.g., 3003 aluminum) than the material that the bolster plate 107 of the LGA package cooling assembly 100 is composed of (e.g., stainless steel, brass, copper). The material that the bolster plate 507 of the improved BGA cooling assembly 500 of FIG. 5e is composed of can also be stronger materials (e.g., steel, brass, copper).

Future generations of semiconductor chip manufacturing technology are expected to result in more I/Os per package and more heat dissipation which will drive larger loading forces (from larger heat sinks) and/or greater board thermal stresses for future BGA package cooling assembly solutions. As such, loading forces of 300 lb or less, 400 lbs or less, or even 500 lbs or less can evolve over time for future BGA package cooling assemblies such as the cooling assembly 500 of FIG. 5e.

At the same time, however, more I/Os per package will likewise drive even more extreme push-back from LGA sockets. Thus, the loading and/or board stress forces that the bolster plates of future BGA package cooling assemblies will support or overcome are expected to remain significantly smaller than the loading forces that bolster plates for future LGA package cooling assemblies are expected to support or overcome.

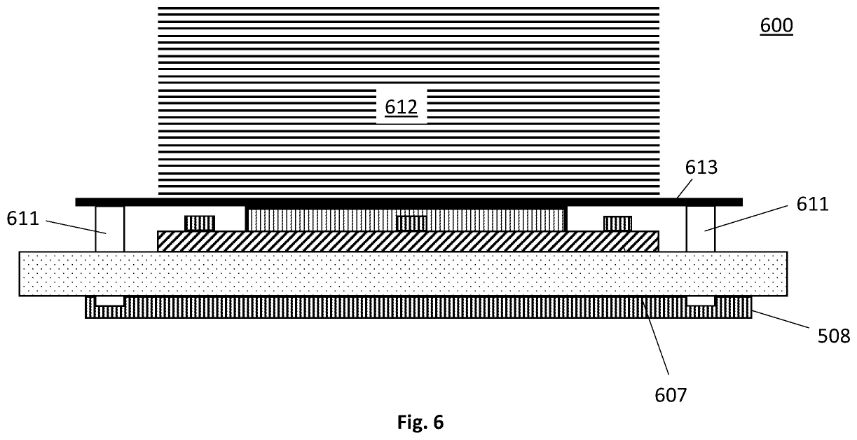

In the improved BGA package cooling assembly embodiment 500 of FIG. 5e, the heat sink is mounted to the bolster plate 507, e.g., as a matter of convenience. FIG. 6 shows an alternative design 600 in which, as per traditional BGA package cooling assembly approaches, the heat sink 612 is mounted to the back plate 608 instead of the bolster plate (spring loading hardware 611 runs through the circuit board 601 between the heat sink base 613 and the back plate 608). Here, again, because of the relatively lighter loading forces associated with a BGA package cooling assembly, the loading forces are permitted to run through the printed circuit board 601.

The improved BGA package cooling assembly approaches 500, 600 can be used, e.g., as a base approach, for a number of different modules that include a printed circuit board and can be plugged in-and-out of an electronic system. Examples include accelerator modules such as Open Compute Project Accelerator Modules (OAMs), or, network adaptor module, to name a few.

OAMs typically include one or more high performance accelerator semiconductor chips (e.g., graphics processors, inference engine processors, machine learning processors, etc.) in one or more BGA packages that are mounted to the OAM's printed circuit board. Networking adaptor modules, such as PCIe adaptor modules, also typically include one or more high performance networking semiconductor chips (e.g., high performance physical layer PHY and/or media access (MAC) chips) in one or more BGA packages that are mounted to the PCIe module's printed circuit board.

In both cases, the entire module, including its printed circuit board, is designed to be plugged in or swapped out of a larger electronic system (e.g., a server computer, a network switch). Because the hardware change is made at the printed circuit board level, the semiconductor chips can be soldered directly to the printed circuit board with allows for BGA packaging of the module's semiconductor chips. This is in contrast to some of the high performance semiconductor chips of a permanent printed circuit board of a larger electronic system (e.g., the motherboard of a server computer), in which case a user or manufacturer may desire to plug such chips in-and-out of the board (e.g., a user or manufacturer may desire to plug CPU chips in/out of the motherboard of a computer). In these situations an LGA package and corresponding socket is more appropriate.

Thus, the solutions 500, 600 of FIGS. 5e and 6 are believed to be particularly appropriate for modules having a printed circuit board that is to plug in-and-out of a larger system and that has a BGA package soldered to the printed circuit board.

Over time, high performance chips having extremely large BGA package sizes and I/O counts are expected to populate such modules (e.g., BGA packages having footprint sizes greater than 5600 mm² and/or more than 5,000 solder balls). The BGA packaging solutions 500, 600 of FIG. 5e or 6 can be used as a base, straightforward approach for any/all such modules to address the particular BGA package exposure to increasing thermally induced circuit board warpage.

Additionally, such modules (being pluggable/unpluggable sub-units) tend to have smaller form factors and are therefore more susceptible to warpage from thermal stress because the footprint of the large BGA chip package(s) consume most of the space of the printed circuit board (the surface area of the printed circuit board is dominated by the large BGA package(s)). Examples of such smaller form factors include (e.g., 165 mm×104 mm (e.g., for OAM), 102 mm×165 mm (e.g., for OAM) and 265 mm×111 mm (for PCIe)).

Although embodiments above have been directed to air cooled cooling assemblies having a heat sink, other embodiments may use liquid cooling of some kind in which the heat sink is replaced by a cold plate (through which cooled liquid flows) or a vapor chamber (within which liquid transfers from liquid phase to vapor phase). Any of a heat sink, cold plate or vapor chamber can be referred to more generally as a cooling mass.

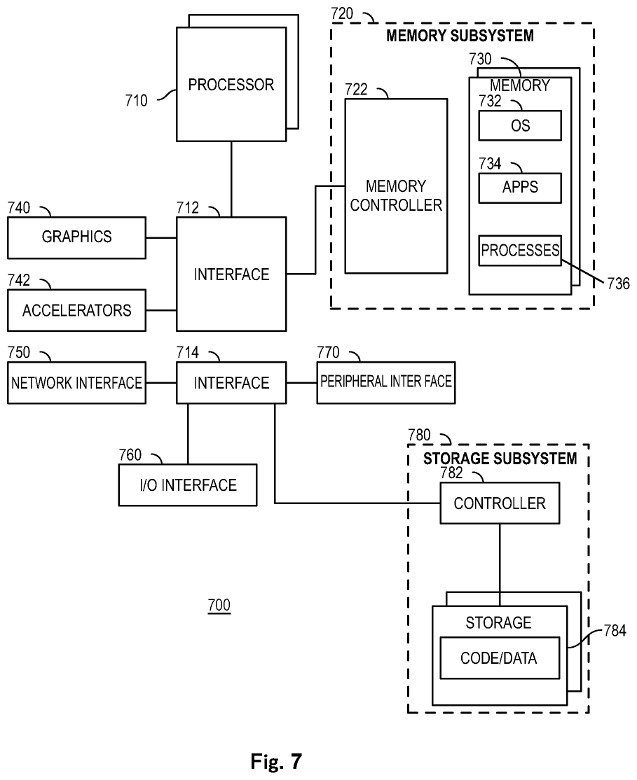

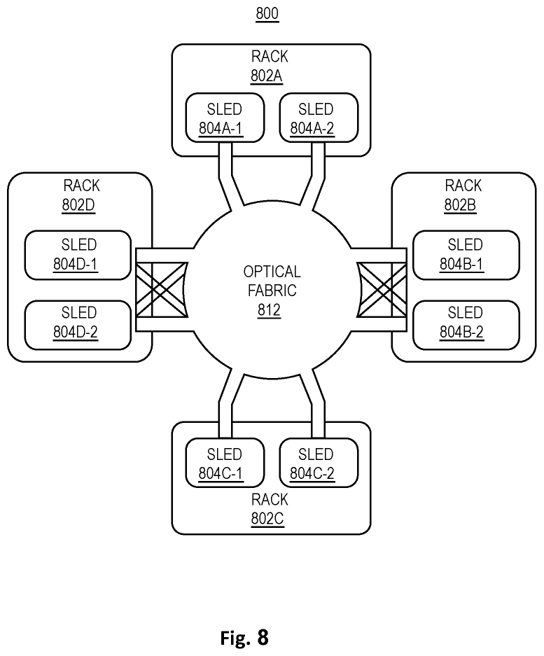

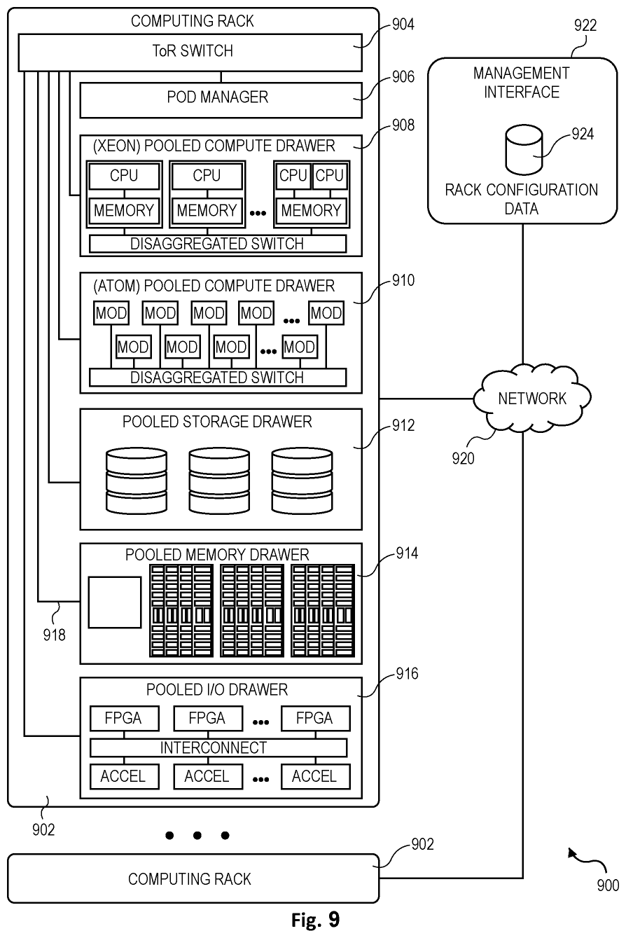

The following discussion concerning FIGS. 7, 8 and 9 are directed to systems, data centers and rack implementations, generally. FIG. 7 generally describes possible features of an electronic system that can include one or more semiconductor chip packages having a cooling assembly that is designed according to the teachings above. For example, a module having a printed circuit board may plug into a system having features described in FIG. 7 where one or more BGA chip packages whose chip(s) are designed to perform the functions of one or more of these features are soldered to the printed circuit board. FIG. 8 describes possible features of a data center that can include such electronic systems. FIG. 9 describes possible features of a rack having one or more such electronic systems installed into it.

FIG. 7 depicts an example system. System 700 includes processor 710, which provides processing, operation management, and execution of instructions for system 700. Processor 710 can include any type of microprocessor, central processing unit (CPU), graphics processing unit (GPU), processing core, or other processing hardware to provide processing for system 700, or a combination of processors. Processor 710 controls the overall operation of system 700, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

Certain systems also perform networking functions (e.g., packet header processing functions such as, to name a few, next nodal hop lookup, priority/flow lookup with corresponding queue entry, etc.), as a side function, or, as a point of emphasis (e.g., a networking switch or router). Such systems can include one or more network processors to perform such networking functions (e.g., in a pipelined fashion or otherwise).

In one example, system 700 includes interface 712 coupled to processor 710, which can represent a higher speed interface or a high throughput interface for system components that needs higher bandwidth connections, such as memory subsystem 720 or graphics interface components 740, or accelerators 742. Interface 712 represents an interface circuit, which can be a standalone component or integrated onto a processor die. Where present, graphics interface 740 interfaces to graphics components for providing a visual display to a user of system 700. In one example, graphics interface 740 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 740 generates a display based on data stored in memory 730 or based on operations executed by processor 710 or both. In one example, graphics interface 740 generates a display based on data stored in memory 730 or based on operations executed by processor 710 or both.

Accelerators 742 can be a fixed function offload engine that can be accessed or used by a processor 710. For example, an accelerator among accelerators 742 can provide compression (DC) capability, cryptography services such as public key encryption (PKE), cipher, hash/authentication capabilities, decryption, or other capabilities or services. In some embodiments, in addition or alternatively, an accelerator among accelerators 742 provides field select controller capabilities as described herein. In some cases, accelerators 742 can be integrated into a CPU socket (e.g., a connector to a motherboard or circuit board that includes a CPU and provides an electrical interface with the CPU). For example, accelerators 742 can include a single or multi-core processor, graphics processing unit, logical execution unit single or multi-level cache, functional units usable to independently execute programs or threads, application specific integrated circuits (ASICs), neural network processors (NNPs), “X” processing units (XPUs), programmable control logic circuitry, and programmable processing elements such as field programmable gate arrays (FPGAs). Accelerators 742 can provide multiple neural networks, processor cores, or graphics processing units can be made available for use by artificial intelligence (AI) or machine learning (ML) models. For example, the AI model can use or include any or a combination of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 720 represents the main memory of system 700 and provides storage for code to be executed by processor 710, or data values to be used in executing a routine. Memory subsystem 720 can include one or more memory devices 730 such as read-only memory (ROM), flash memory, volatile memory, or a combination of such devices. Memory 730 stores and hosts, among other things, operating system (OS) 732 to provide a software platform for execution of instructions in system 700. Additionally, applications 734 can execute on the software platform of OS 732 from memory 730. Applications 734 represent programs that have their own operational logic to perform execution of one or more functions. Processes 736 represent agents or routines that provide auxiliary functions to OS 732 or one or more applications 734 or a combination. OS 732, applications 734, and processes 736 provide software functionality to provide functions for system 700. In one example, memory subsystem 720 includes memory controller 722, which is a memory controller to generate and issue commands to memory 730. It will be understood that memory controller 722 could be a physical part of processor 710 or a physical part of interface 712. For example, memory controller 722 can be an integrated memory controller, integrated onto a circuit with processor 710. In some examples, a system on chip (SOC or SoC) combines into one SoC package one or more of: processors, graphics, memory, memory controller, and Input/Output (I/O) control logic circuitry.

A volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/Output version 2, JESD229-2 originally published by JEDEC in August 2014, HBM (High Bandwidth Memory), JESD235, originally published by JEDEC in October 2013, LPDDR5, HBM2 (HBM version 2), or others or combinations of memory technologies, and technologies based on derivatives or extensions of such specifications.

In various implementations, memory resources can be “pooled”. For example, the memory resources of memory modules installed on multiple cards, blades, systems, etc. (e.g., that are inserted into one or more racks) are made available as additional main memory capacity to CPUs and/or servers that need and/or request it. In such implementations, the primary purpose of the cards/blades/systems is to provide such additional main memory capacity. The cards/blades/systems are reachable to the CPUs/servers that use the memory resources through some kind of network infrastructure such as CXL, CAPI, etc.

The memory resources can also be tiered (different access times are attributed to different regions of memory), disaggregated (memory is a separate (e.g., rack pluggable) unit that is accessible to separate (e.g., rack pluggable) CPU units), and/or remote (e.g., memory is accessible over a network).

While not specifically illustrated, it will be understood that system 700 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect express (PCIe) bus, a HyperTransport or industry standard architecture (ISA) bus, a small computer system interface (SCSI) bus, Remote Direct Memory Access (RDMA), Internet Small Computer Systems Interface (iSCSI), NVM express (NVMe), Coherent Accelerator Interface (CXL), Coherent Accelerator Processor Interface (CAPI), Cache Coherent Interconnect for Accelerators (CCIX), Open Coherent Accelerator Processor (Open CAPI) or other specification developed by the Gen-z consortium, a universal serial bus (USB), or an Institute of Electrical and Electronics Engineers (IEEE) standard 1394 bus.

In one example, system 700 includes interface 714, which can be coupled to interface 712. In one example, interface 714 represents an interface circuit, which can include standalone components and integrated circuitry. In one example, multiple user interface components or peripheral components, or both, couple to interface 714. Network interface 750 provides system 700 the ability to communicate with remote devices (e.g., servers or other computing devices) over one or more networks. Network interface 750 can include an Ethernet adapter, wireless interconnection components, cellular network interconnection components, USB (universal serial bus), or other wired or wireless standards-based or proprietary interfaces. Network interface 750 can transmit data to a remote device, which can include sending data stored in memory. Network interface 750 can receive data from a remote device, which can include storing received data into memory. Various embodiments can be used in connection with network interface 750, processor 710, and memory subsystem 720.

In one example, system 700 includes one or more input/output (I/O) interface(s) 760. I/O interface 760 can include one or more interface components through which a user interacts with system 700 (e.g., audio, alphanumeric, tactile/touch, or other interfacing). Peripheral interface 770 can include any hardware interface not specifically mentioned above. Peripherals refer generally to devices that connect dependently to system 700. A dependent connection is one where system 700 provides the software platform or hardware platform or both on which operation executes, and with which a user interacts.

In one example, system 700 includes storage subsystem 780 to store data in a nonvolatile manner. In one example, in certain system implementations, at least certain components of storage 780 can overlap with components of memory subsystem 720. Storage subsystem 780 includes storage device(s) 784, which can be or include any conventional medium for storing large amounts of data in a nonvolatile manner, such as one or more magnetic, solid state, or optical based disks, or a combination. Storage 784 holds code or instructions and data in a persistent state (e.g., the value is retained despite interruption of power to system 700). Storage 784 can be generically considered to be a “memory,” although memory 730 is typically the executing or operating memory to provide instructions to processor 710. Whereas storage 784 is nonvolatile, memory 730 can include volatile memory (e.g., the value or state of the data is indeterminate if power is interrupted to system 700). In one example, storage subsystem 780 includes controller 782 to interface with storage 784. In one example controller 782 is a physical part of interface 714 or processor 710 or can include circuits in both processor 710 and interface 714.

A non-volatile memory (NVM) device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

Such non-volatile memory devices can be placed on a DIMM and cooled according to the teachings above.

A power source (not depicted) provides power to the components of system 700. More specifically, power source typically interfaces to one or multiple power supplies in system 700 to provide power to the components of system 700. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 700 can be implemented as a disaggregated computing system. For example, the system 700 can be implemented with interconnected compute sleds of processors, memories, storages, network interfaces, and other components. High speed interconnects can be used such as PCIe, Ethernet, or optical interconnects (or a combination thereof). For example, the sleds can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Although a computer is largely described by the above discussion of FIG. 7, other types of systems to which the above described invention can be applied and are also partially or wholly described by FIG. 7 are communication systems such as routers, switches and base stations.

FIG. 8 depicts an example of a data center. Various embodiments can be used in or with the data center of FIG. 8. As shown in FIG. 8, data center 800 may include an optical fabric 812. Optical fabric 812 may generally include a combination of optical signaling media (such as optical cabling) and optical switching infrastructure via which any particular sled in data center 800 can send signals to (and receive signals from) the other sleds in data center 800. However, optical, wireless, and/or electrical signals can be transmitted using fabric 812. The signaling connectivity that optical fabric 812 provides to any given sled may include connectivity both to other sleds in a same rack and sleds in other racks.

Data center 800 includes four racks 802A to 802D and racks 802A to 802D house respective pairs of sleds 804A-1 and 804A-2, 804B-1 and 804B-2, 804C-1 and 804C-2, and 804D-1 and 804D-2. Thus, in this example, data center 800 includes a total of eight sleds. Optical fabric 812 can provide sled signaling connectivity with one or more of the seven other sleds. For example, via optical fabric 812, sled 804A-1 in rack 802A may possess signaling connectivity with sled 804A-2 in rack 802A, as well as the six other sleds 804B-1, 804B-2, 804C-1, 804C-2, 804D-1, and 804D-2 that are distributed among the other racks 802B, 802C, and 802D of data center 800. The embodiments are not limited to this example. For example, fabric 812 can provide optical and/or electrical signaling.

FIG. 9 depicts an environment 900 that includes multiple computing racks 902, each including a Top of Rack (ToR) switch 904, a pod manager 906, and a plurality of pooled system drawers. Generally, the pooled system drawers may include pooled compute drawers and pooled storage drawers to, e.g., effect a disaggregated computing system. Optionally, the pooled system drawers may also include pooled memory drawers and pooled Input/Output (I/O) drawers. In the illustrated embodiment the pooled system drawers include an INTEL® XEON® pooled computer drawer 908, and INTEL® ATOM™ pooled compute drawer 910, a pooled storage drawer 912, a pooled memory drawer 914, and a pooled I/O drawer 916. Each of the pooled system drawers is connected to ToR switch 904 via a high-speed link 918, such as a 40 Gigabit/second (Gb/s) or 100 Gb/s Ethernet link or an 100+Gb/s Silicon Photonics (SiPh) optical link. In one embodiment high-speed link 918 comprises an 600 Gb/s SiPh optical link.

Again, the drawers can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Multiple of the computing racks 900 may be interconnected via their ToR switches 904 (e.g., to a pod-level switch or data center switch), as illustrated by connections to a network 920. In some embodiments, groups of computing racks 902 are managed as separate pods via pod manager(s) 906. In one embodiment, a single pod manager is used to manage all of the racks in the pod. Alternatively, distributed pod managers may be used for pod management operations. RSD environment 900 further includes a management interface 922 that is used to manage various aspects of the RSD environment. This includes managing rack configuration, with corresponding parameters stored as rack configuration data 924.

Any of the systems, data centers or racks discussed above, apart from being integrated in a typical data center, can also be implemented in other environments such as within a bay station, or other micro-data center, e.g., at the edge of a network.

Embodiments herein may be implemented in various types of computing, smart phones, tablets, personal computers, and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

Some examples may be implemented using or as an article of manufacture or at least one computer-readable medium. A computer-readable medium may include a non-transitory storage medium to store program code. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the program code implements various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

To the extent any of the teachings above can be embodied in a semiconductor chip, a description of a circuit design of the semiconductor chip for eventual targeting toward a semiconductor manufacturing process can take the form of various formats such as a (e.g., VHDL or Verilog) register transfer level (RTL) circuit description, a gate level circuit description, a transistor level circuit description or mask description or various combinations thereof. Such circuit descriptions, sometimes referred to as “IP Cores”, are commonly embodied on one or more computer readable storage media (such as one or more CD-ROMs or other type of storage technology) and provided to and/or otherwise processed by and/or for a circuit design synthesis tool and/or mask generation tool. Such circuit descriptions may also be embedded with program code to be processed by a computer that implements the circuit design synthesis tool and/or mask generation tool.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences may also be performed according to alternative embodiments. Furthermore, additional sequences may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

1. An apparatus, comprising:
a ball grid array (BGA) chip package cooling assembly comprising a) and b) below:
a) a back plate;
b) a bolster plate, the bolster plate having frame arms, the BGA chip package to be placed in a window formed by the frame arms and soldered to a region of a printed circuit board, the frame arms surrounding the region, the printed circuit board to be under a compressive force between the back plate and the bolster plate.

2. The apparatus of claim 1 wherein the BGA chip package cooling assembly further comprises a cooling mass having a base and spring loading hardware, the cooling mass having a base to be coupled to the bolster plate through the spring loading hardware.

3. The apparatus of claim 1 wherein a loading force applied by the spring loading hardware is 500 lbs or less.

4. The apparatus of claim 3 wherein the BGA chip package has more than 5,000 I/Os.

5. The apparatus of claim 1 wherein the BGA chip package cooling assembly further comprises a cooling mass having a base and spring loading hardware, the cooling mass to be coupled to the back plate through the spring loading hardware.

6. The apparatus of claim 1 wherein a loading force applied by the spring loading hardware is 500 lbs or less.

7. The apparatus of claim 3 wherein the BGA chip package has more than 5,000 I/Os.

8. The apparatus of claim 1 wherein the compressive force is to diminish thermally induced warpage of the printed circuit board within the region

9. An apparatus, comprising:
a module to plug into an electronic system, the module comprising a), b), c) and d) below:
a) a ball grid array (BGA) chip package;
b) a printed circuit board, the BGA chip package soldered to a region of a printed circuit board;
c) a back plate; and,
d) a bolster plate, the bolster plate having frame arms, the BGA chip package placed in a window formed by the frame arms, the frame arms surrounding the region, the printed circuit board to be subjected to a compressive force between the back plate and the bolster plate.

10. The apparatus of claim 9 wherein the BGA chip package cooling assembly further comprises a cooling mass having a base and spring loading hardware, the cooling mass base to be coupled to the bolster plate through the spring loading hardware.

11. The apparatus of claim 9 wherein a loading force applied by the spring loading hardware is 500 lbs or less.

12. The apparatus of claim 11 wherein the BGA chip package has more than 5,000 I/Os.

13. The apparatus of claim 9 wherein the BGA chip package cooling assembly further comprises a cooling mass having a base and spring loading hardware, the cooling mass base to be coupled to the back plate through the spring loading hardware.

14. The apparatus of claim 9 wherein a loading force applied by the spring loading hardware is 500 lbs or less.

15. The apparatus of claim 11 wherein the BGA chip package has more than 5,000 I/Os.

16. The apparatus of claim 9 wherein the module is one of:
an OAM module;
a PCIe module.

17. A data center, comprising:
a plurality of racks, the plurality of racks comprising respective electronic systems, the respective electronic systems communicatively coupled by way of one or more networks, an electronic system of the respective electronic systems comprising a module that is plugged into the electronic system, the module comprising a), b), c) and d) below:
a) a ball grid array (BGA) chip package;
b) a printed circuit board, the BGA chip package soldered to a region of a printed circuit board;
c) a back plate; and,
d) a bolster plate, the bolster plate having frame arms, the BGA chip package placed in a window formed by the frame arms, the frame arms surrounding the region, the printed circuit board to be subjected to a compressive force between the back plate and the bolster plate.

18. The data center of claim 17 wherein the BGA chip package cooling assembly further comprises a cooling mass having a base and spring loading hardware, the cooling mass base to be coupled to the bolster plate through the spring loading hardware.

19. The data center of claim 18 wherein a loading force applied by the spring loading hardware is 500 lbs or less.

20. The data center of claim 19 wherein the BGA chip package has more than 5,000 I/Os.
